(19) United States
(12) Patent Application Publication
(10) Pub. No.: US 2026/0198307 A1
(43) Pub. Date: Jul. 9, 2026

(54) CHIP PACKAGING METHOD AND DEVICE

(71) Applicant: Ningbo S J Electronics Co., Ltd., Ningbo (CN)

(72) Inventors: Fay HUA, Ningbo (CN); Youngjin KIM, Ningbo (CN); Mina YAGHMAZADEH, Ningbo (CN)

(21) Appl. No.: 19/128,459

(22) PCT Filed: Apr. 23, 2023
(86) PCT No.: PCT/CN2023/090060

§ 371 Date: May 8, 2025

(30) Foreign Application Priority Data
Nov. 8, 2022 (CN) 202211394478.8

(51) Int. Cl. H10W 40/00; H10P 72/00; H10W 40/20; H10W 74/01

(52) U.S. Cl. CPC H10W 40/037; H10P 72/0438; H10W 40/235; H10W 74/01

(57) ABSTRACT

A chip packaging method includes: arranging a sealing material on a substrate on which a chip is placed; placing, on an upper surface of the chip, a layered indium structure which includes at least a protective layer for a surface which is in contact with the chip, and a protective layer for a face opposite to the surface which is in contact with the chip; placing, on an upper surface of the substrate, a heat dissipation structure which is bonded to the sealing material to form a first prefabricated member; curing the sealing material in the first prefabricated member at a first temperature as a peak temperature, to form a second prefabricated member; and connecting the chip, the layered indium structure and the heat dissipation structure of the second prefabricated member at a second temperature as a peak temperature.

### TECHNICAL FIELD

The present invention relates to the field of semiconductor packaging, in particular to a chip packaging method and device.

### BACKGROUND

During the packaging process, an indium sheet is employed as a thermal interface material, and a soldering flux assists a chip to be soldered with a heat-conducting cover plate. During reflow soldering, the indium material may splash, causing short circuits between surrounding capacitors and chips, and meanwhile, causing the formation of voids in the thermal interface of the indium sheet, thereby damaging the heat-conducting interface. Moreover, in subsequent reflow soldering during packaging, splashing and the void formation may be further aggravated, ultimately resulting in a sharp decline in the chip reliability and the heat dissipation performance, leading to a failure of semiconductor device. As shown in FIG. 1, a case where the void formation is aggravated during the plurality of reflow soldering process is illustrated. In the prior art, the soldering flux is applied onto both interfaces to be soldered to remove an oxide layer of indium during the reflow soldering process, achieving an oxide-free surface layer of indium, enabling a chip metal coating with a wetting surface and a heat dissipation cover plate to establish a metallurgical bonding, and improving the coverage rate of a connecting face. However, although the soldering flux provides an oxide-free indium surface, its residue may be trapped between the indium and the chip, or between the indium and the heat dissipation cover plate, and it is still apt to form voids in the subsequent reflow soldering process.

### SUMMARY

In order to solve the technical problems existing in the prior art such as high voidage of thermal interface and the dependence on vacuum during the packaging process, the present invention provides a chip packaging method, including:
arranging a sealing material on a substrate on which a chip is placed;
placing, on an upper surface of the chip, a layered indium structure which includes at least a protective layer on a surface which is in contact with the chip, and a protective layer on a face opposite to the surface which is in contact with the chip;
placing, on an upper surface of the substrate, a heat dissipation structure which is bonded to the sealing material to form a first prefabricated member;
curing the sealing material in the first prefabricated member at a first temperature as a peak temperature, to form a second prefabricated member; and
connecting the chip, the layered indium structure and the heat dissipation structure of the second prefabricated member at a second temperature as a peak temperature;
where the first temperature is lower than a melting point of indium, and the second temperature is higher than the melting point of indium; and
the protective layer volatilizes before the layered indium structure melts.

Preferably, the connecting the second prefabricated member at the second temperature as the peak temperature is not limited to a vacuum environment.

Preferably, a method for forming the layered indium structure includes: bringing a solution in which paraffin or resin is dissolved into contact with an indium sheet, allowing the solution to adhere to a surface of the indium sheet, wherein an organic solvent in the solution volatilizes, and the paraffin or resin adheres to the surface of the indium sheet, thereby forming the layered indium structure.

Preferably, the chip packaging method includes: arranging a connection structure on a lower surface of the substrate; where:
the connection between the connection structure and the lower surface of the substrate occurs simultaneously with the connection of the second prefabricated member at the second temperature as the peak temperature;
or,
the connection between the connection structure and the lower surface of the substrate occurs after the connection of the second prefabricated member at the second temperature as the peak temperature, and the connection structure and the lower surface of the substrate are connected at a third temperature as a peak temperature.

Preferably, the connection structure is solder balls.

Preferably, the first temperature ranges from 30° C. to 150° C.

Preferably, the second temperature ranges from 157° C. to 300° C.

Preferably, when the connection between the connection structure and the lower surface of the substrate occurs simultaneously with the connection of the second prefabricated member at the second temperature as the peak temperature, the second temperature ranges from 220° C. to 300° C.; and
when the connection between the connection structure and the lower surface of the substrate occurs after the connection of the second prefabricated member at the second temperature as the peak temperature, and the connection structure and the lower surface of the substrate are connected at the third temperature as the peak temperature, the second temperature ranges from 157° C. to 200° C., and the third temperature ranges from 220° C. to 300° C.

Preferably, an active agent is provided outside the protective layer, and the active agent is used to clean the surface of the protective layer which is in contact with the chip, and the surface of the face opposite to the surface of the protective layer which is in contact with the chip.

A chip packaging device, including: a first workstation, a second workstation, a third workstation, a fourth workstation and a fifth workstation; where:
the first workstation is configured to arrange a sealing material on a substrate on which a chip is placed;
the second workstation is configured to place, on an upper surface of the chip, a layered indium structure which includes at least a protective layer on a surface which is in contact with the chip, and a protective layer on a face opposite to the surface which is in contact with the chip;
the third workstation is configured to place, on an upper surface of the substrate, a heat dissipation structure to form a first prefabricated member;
the fourth workstation is configured to cure the sealing material to form a second prefabricated member; and a method for curing the sealing material includes: curing the sealing material at a first temperature as a peak temperature;
where the first temperature is lower than a melting point of indium;
the fifth workstation is configured to connect a second prefabricated member, and a method for connecting the second prefabricated member includes: connecting the chip, the layered indium structure and the heat dissipation structure of the second prefabricated member at a second temperature as a peak temperature;
where the second temperature is higher than the melting point of indium; and the protective layer volatilizes before the layered indium structure melts.

Preferably, the connecting the second prefabricated member at the second temperature as the peak temperature is not limited to a vacuum environment.

Preferably, the packaging device further includes a sixth workstation, where the sixth workstation is configured to connect the connection structure with the lower surface of the substrate;
the connection between the connection structure and the lower surface of the substrate occurs simultaneously with the connection of the second prefabricated member at the second temperature as the peak temperature;
or,
the connection between the connection structure and the lower surface of the substrate occurs after the connection of the second prefabricated member at the second temperature as the peak temperature, and the connection structure and the lower surface of the substrate are connected with a third temperature as a peak temperature.

Preferably, the connection structure is solder balls.

Preferably, the first temperature ranges from 30° C. to 150° C.

Preferably, the second temperature ranges from 157° C. to 300° C.

Preferably, when the connection between the connection structure and the lower surface of the substrate occurs simultaneously with the connection of the second prefabricated member at the second temperature as the peak temperature, the second temperature ranges from 220° C. to 300° C.; and
when the connection between the connection structure and the lower surface of the substrate occurs after the connection of the second prefabricated member at the second temperature as the peak temperature, and the connection structure and the lower surface of the substrate are connected at the third temperature as the peak temperature, the second temperature ranges from 157° C. to 200° C., and the third temperature ranges from 220° C. to 300° C.

Preferably, the second workstation and the third workstation are the same workstation, which sequentially performs the placement of the layered indium structure on the upper surface of the chip and the placement of the heat dissipation structure on the upper surface of the substrate.

Preferably, the first workstation, the second workstation and the third workstation are the same workstation, which sequentially performs the arrangement of the sealing material on the substrate on which the chip is placed, the placement of the layered indium structure on the upper surface of the chip and the placement of the heat dissipation structure on the upper surface of the substrate.

Preferably, the fourth workstation and the fifth workstation are the same workstation, which sequentially performs the curing of the sealing material and the connection of the second prefabricated member.

Preferably, the fifth workstation and the sixth workstation are a same workstation, which sequentially performs the connecting of the second prefabricated member and the connecting of the connection structure with the lower surface of the substrate, or simultaneously performs the connecting of the second prefabricated member and the connecting of the connection structure with the lower surface of the substrate.

Preferably, the fourth workstation, the fifth workstation and the sixth workstation are the same workstation, which sequentially performs the curing of the sealing material, the connection of the second prefabricated member and the connection of the connection structure with the lower surface of the substrate;
or, after performing the curing of the sealing material, simultaneously performs the connection of the second prefabricated member and the connection of the connection structure with the lower surface of the substrate.

The chip packaging method provided by the present invention adopts a process of first curing and sealing and then performing reflow soldering in combination with the protective layer, which avoids a need for a necessary vacuum environment during reflow soldering, reduces the vacuum pumping time, improves the packaging efficiency, and simplifies the process conditions. According to the present invention, the layered indium structure is obtained by attaching the protective layer to the indium sheet, eliminating the need for the soldering flux. This effectively improves the void conditions of the connecting face, and enhances the coverage rate of the connecting face, Moreover, the layered indium structure provided with the protective layer achieves a bonding effect comparable to that of the indium sheet with the soldering flux, without impacting the packaging. With improved coverage rate achieved under a condition of the layered indium structure without the soldering flux, the present invention enables the process to be adjusted and integrates the flows, avoiding the shift between elements, especially the shift of the layered indium structure relative to the chip, and improving the packaging efficiency and stability.

### BRIEF DESCRIPTION OF THE DRAWINGS

In order to illustrate the technical solution in the inventive embodiments or the prior art more clearly, the accompanying drawings needed to be used in the description of the embodiments or the prior art will be briefly introduced below. Apparently, the drawings in the following description are merely some of the embodiments of the present invention, and for ordinary skilled in the art, other drawings can be obtained according to such drawings without paying any creative labour.

FIG. 1 is a cross-sectional view of a soldering face employing a soldering flux.

FIG. 2 is a structural diagram of a chip packaged according to a chip packaging method provided by Embodiment 1.

FIG. 3 is a structural diagram of a chip packaged in a BGA manner according to the chip packaging method provided by Embodiment 1.

FIG. 4 is a structural diagram of a chip packaged in a PGA manner according to the chip packaging method provided by Embodiment 1.

FIG. 5 is a structural diagram of a chip packaged in an LGA manner according to the chip packaging method provided by Embodiment 1.

FIG. 6 is a structural diagram of a layered indium structure in the chip packaging method provided by Embodiment 1.

FIG. 7 shows a soldering face after a first reflow soldering using the traditional process with a soldering flux sheet in a first group of tests.

FIG. 8 shows a soldering face after a first reflow soldering using the packaging method provided by Embodiment 1 in the first group of tests.

FIG. 9 shows a soldering face after a second reflow soldering using the traditional process with the soldering flux sheet in the first group of tests.

FIG. 10 shows a soldering face after a second reflow soldering using the packaging method provided by Embodiment 1 in the first group of tests.

FIG. 11 shows a comparison of a coverage rate distribution, in the first group of tests, between the chip packaging method provided by Embodiment 1 and the traditional process using the soldering flux sheet, after the first and second reflow soldering.

FIG. 12 shows a soldering face after a first reflow soldering using the traditional process with a soldering flux sheet in a second group of tests.

FIG. 13 shows a soldering face after a first reflow soldering using the packaging method provided by Embodiment 1 in the second group of tests.

FIG. 14 shows a soldering face after a second reflow soldering using the traditional process with the soldering flux sheet in the second group of tests.

FIG. 15 shows a soldering face after a second reflow soldering using the packaging method provided by Embodiment 1 in the second group of tests.

FIG. 16 shows a comparison of a coverage rate distribution, in the second group of tests, between the chip packaging method provided by Embodiment 1 and the traditional process using the soldering flux sheet, after the first and second reflow soldering.

FIG. 17 shows a soldering face using the packaging method provided by Embodiment 1 in a third group of tests.

FIG. 18 shows a coverage rate distribution of the packaging method provided by Embodiment 1.

FIG. 19 shows a soldering face using the packaging method provided by Embodiment 1 in a fourth group of tests.

FIG. 20 shows a coverage rate distribution of the packaging method provided by Embodiment 1 in the fourth group of tests.

### DETAILED DESCRIPTION OF THE EMBODIMENTS

In order to better understand the above objectives, features and advantages of the present invention, a more detailed description of the present invention will be provided in conjunction with the accompanying drawings and the specific implementations. It should be noted that the embodiments of the present application and the features in the embodiments can be combined with each other without conflict.

In the following description, numerous specific details are elaborated to facilitate a thorough understanding of the present invention. However, the present invention can also be implemented in other ways than those described herein. Therefore, the protection scope of the present invention is not limited by the specific embodiments disclosed below.

### Embodiment 1

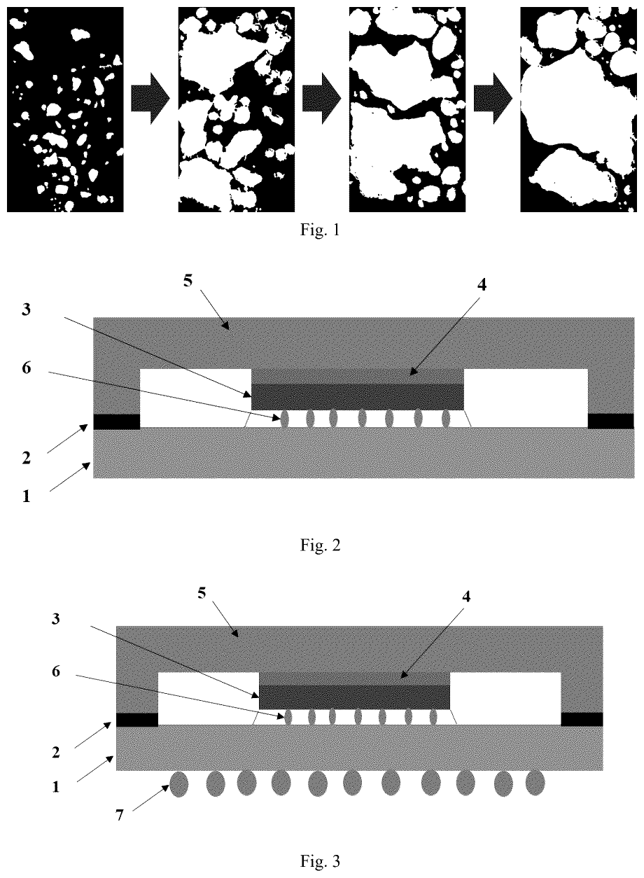

This embodiment provides a chip 3 packaging method, forming a packaging device as shown in FIG. 2-FIG. 5. As shown in FIG. 2, the packaging device includes: a substrate 1, a sealant 2 coated on the substrate 1, a heat dissipation cover plate 5 bonded to the sealant 2, a chip 3 provided on the substrate 1, an interconnection structure 6 in the chip 3, and a layered indium structure 4 provided on the chip 3.

The packaging method includes the following operations.

The substrate 1 with the chip 3 placed on its upper surface is placed on a first workstation, and the sealant 2 is coated on the substrate 1 around the chip 3.

The substrate 1 coated with the sealant 2 is transferred to the next workstation, where the layered indium structure 4 is placed on an upper surface of the chip 3. Without the need for workstation turnover, at the same workstation, the heat dissipation cover plate 5 is placed on the upper surface of the substrate 1 where the layered indium structure 4 has been placed.

In contrast, a typical process of a chip packaging method requiring a soldering flux includes: coating an upper surface of a chip with the soldering flux; transferring it to the next workstation, and placing an indium sheet on the surface of the chip coated with the soldering flux; transferring it to the next workstation, and coating an upper surface of the indium sheet with the soldering flux; transferring it to the next workstation, and coating a sealant on the substrate around the chip; transferring it to the next workstation, and placing a heat dissipation cover plate at the position of the sealant on the substrate; and transferring it to the next workstation, and curing the sealant by hot pressing. In this embodiment, no soldering flux is needed, which provides conditions for improving the process of the sealant, the layered indium structure and the heat dissipation cover plate, thereby avoiding unnecessary workstation turnover. Moreover, since the heat dissipation cover plate is pressed on the layered indium structure, even if the packaging structure moves in the subsequent process, the layered indium structure will not shift from the fixed position on the upper surface of the chip, thereby improving the packaging stability.

The surface of the layered indium structure 4 provided by this embodiment does not require any soldering flux, and the need for a first soldering flux applying process is eliminated before the layered indium structure 4 is placed on the upper surface of the chip 3. After the layered indium structure 4 is placed on the upper surface of the chip 3 and before the heat dissipation cover plate 5 or another heat dissipation structure is superimposed, the need for a second soldering flux applying process is also eliminated. This saves the time for applying the soldering flux for two times, and optimizes the process flows. In addition, the layered indium structure 4 without the soldering flux avoids the risk of the soldering flux residue being trapped between the indium and the chip 3, or between the indium and the heat dissipation cover plate 1, thereby preventing void formation in the indium sheet during subsequent reflow soldering.

The area of the layered indium structure 4 is 0.5-30% larger than that of the chip 3, preferably 5-15% larger, more preferably 7-12% larger. The surface of the layered indium structure 4 is coated with a protective layer, which prevents the layered indium structure 4 from being oxidized, and allows the layered indium structure 4 to completely volatilize in the subsequent high-temperature process. The temperature of the protective layer is lower than a melting point of indium, so that an oxide-free indium surface can be presented after the protective layer volatilizes. When the reflow soldering process reaches its peak temperature—the melting point of indium, indium melts and serves as the soldering flux to wet the chip 3 and the heat dissipation cover plate 5 and form a bond at the interface, completing soldering. In the traditional indium soldering process, the soldering flux is needed, serving as a temporary glue to attach the indium sheet to the surface of the chip 3. The packaging method provided by this embodiment does not use the soldering flux and achieves temporary adhesion by applying pressure, enabling the layered indium structure 4, serving as thermal interface material (TIM), to be pressed on the chip 3 without the soldering flux, thereby achieving the temporary adhesion. A pressure of more than 0.01 kg (0.1 N/mm²) is needed to be applied per 1 mm² of the layered indium structure 4 without the soldering flux. After the pressure is applied, the layered indium structure 4 will not slide off under a repeated acceleration of more than 5 m/s², that is, higher than the speed of the arms of most fast-moving robots. Therefore, the above process of achieving the adhesion without the soldering flux can be handled normally without extra caution. It is unnecessary to apply a force of more than 0.01 kg to every 1 mm² while placing the layered indium structure 4. Regardless of the size of the layered indium structure 4 without the soldering flux, a force of 100N can be applied to a local region of 10*10 mm to achieve a spot adhesion. In addition, the use of droplets can also provide the temporary adhesion. For example, deionized water, isopropanol, ethane alcohol or any liquid with a volatilization temperature below 110° C. can be used.

The surface of the layered indium structure 4 is provided with a protective layer. A method for forming the layered indium structure 4 includes: bringing a solution in which paraffin or resin is dissolved into contact with an indium sheet such that the solution adheres to a surface of the indium sheet, wherein an organic solvent in the solution volatilizes, and the paraffin or resin adheres to the surface of the indium sheet, thereby forming the layered indium structure. A way for bringing the solution in which paraffin or resin is dissolved into contact with the indium sheet includes: placing the indium sheet in the solution, or spraying the solution onto the indium sheet, or the like. This embodiment does not limit the contact approaches, and the implementation of different contact approaches does not affect the realization of the technical effect of this embodiment. The solution is a non-corrosive organic-based solution, which conforms to the regulations for RoHS and REACH, and specifically includes an active agent, paraffin or resin, and organic solvent capable of dissolving the paraffin or resin. The active agent is preferably an organic acid or a combination of the organic acid and an inorganic acid. When the indium sheet is placed in the solution, the surface treatment and the protective layer arrangement both are completed simultaneously. The surface treatment involves removing the oxide layer from the surface of the indium sheet using the organic acid, obtaining a pure indium sheet. Then, the solution is attached to the surface of the pure indium sheet. Upon taking the pure indium sheet out of the solution, the organic solvent capable of dissolving the paraffin or resin volatilizes, leaving the paraffin or resin to be attached to the surface of the pure indium sheet, thereby forming the protective layer for the layered indium structure 4. In this embodiment, an ultra-thin protective layer is provided to protect the surface of the layered indium structure 4, effectively preventing the layered indium structure 4 from being oxidized during subsequent treatment, storage, transportation and the like and before reflow soldering. In the high-temperature environment and during the indium reflow soldering process, the ultra-thin protective layer completely volatilizes, exposing the surface of the oxide-free indium solder to achieve the optimal wetting effect and avoid the void formation.

In some embodiments, an active agent is provided outside the protective layer on the surface of the layered indium structure 4. As shown in FIG. 6, a structural diagram of a layered indium structure provided with a granular active agent is illustrated, where 10 represents the indium sheet, 11 represents the protective layer, and 12 represents the active agent. The form of the active agent is not limited, and can be granular or layered, both of which do not affect the realization of the technical effect of this embodiment. The active agent is used to clean the oxide from the surface of the protective layer for the layered indium structure which is in contact with the chip, and the oxide from the surface of the face opposite to the surface of the protective layer for the layered indium structure which is in contact with the chip. The approach for attaching the active agent to the protective layer on the surface of the layered indium structure 4 is not limited, and can be performed simultaneously during the arrangement of the protective layer, or can be formed by coating and spraying after the protective layer is formed.

The substrate 1 on which the layered indium structure 4 and the heat dissipation cover plate 5 are placed is transferred to the next workstation. The sealant 2 is cured by hot pressing, with a temperature for hot pressing ranging from 30° C. to 150° C., more preferably ranges from 70° C. to 130° C., and more preferably is 120° C. During the curing of the sealant 2 process by hot pressing, a sealed cavity is formed between the heat dissipation cover plate 5 and the substrate 1, providing conditions for subsequent soldering in a non-vacuum environment. At the same time, the protective layer on the surface of the layered indium structure 4 volatilizes with heating, and exposes the surface of the layered indium structure 4 without neither oxidation nor protective layer, which prepares the pure indium to form an intermetallic compound with the metal plating layer on the chip 3 or the heat dissipation cover plate 5, thereby completing the soldering without the soldering flux.

The chip 3 and the heat dissipation cover plate 5 are connected through the reflow soldering process. The peak temperature of the reflow soldering process ranges from 157° C. to 300° C., preferably is 170° C. Since the surface of the layered indium structure 4 is not oxidized, the heat dissipation cover plate 5 and the substrate 1 have been cured by the sealant 2, and the periphery of the layered indium structure 4 is in a sealed environment. Therefore, the above reflow soldering process does not need to be performed in a vacuum environment to prevent the layered indium structure 4 from being oxidized. When the temperature during the reflow soldering process reaches the melting point of indium, the layered indium structure 4 wets the chip 3 and forms a bond at the interface. The reflow soldering process provided by this embodiment no longer needs the vacuum environment, which simplifies the packaging processes. In some embodiments, the curing process of the sealant 2 can be combined with the indium reflow soldering process, which is especially advantageous for LGA packaging.

A connection structure is provided on the lower surface of the substrate 1, and the substrate 1 and the connection structure are connected through the reflow soldering process. The peak temperature during the reflow soldering process ranges from 220° C. to 300° C., preferably is 260° C. Similarly, the above reflow soldering process does not need the vacuum environment.

In some embodiments, the reflow soldering process for the layered indium structure and the reflow soldering process for the connection structure on the lower surface of the substrate can be combined into a single reflow soldering process, with a peak temperature ranging from 220° C. to 300° C. A single high-temperature reflow soldering process is employed to replace the two-step low-temperature reflow soldering process for the layered indium structure 4 and the high-temperature reflow soldering process for the connection structure. This process simultaneously achieves the soldering of both indium attachment and connection structure attachment. The packaging method employing the soldering flux, or the traditional packaging method that requires the prevention of oxide formation on the surface of the indium sheet reply on vacuum conditions and cannot support the process of simultaneously performing the reflow soldering for both the layered indium structure and the connection structure on lower surface of the substrate in this embodiment.

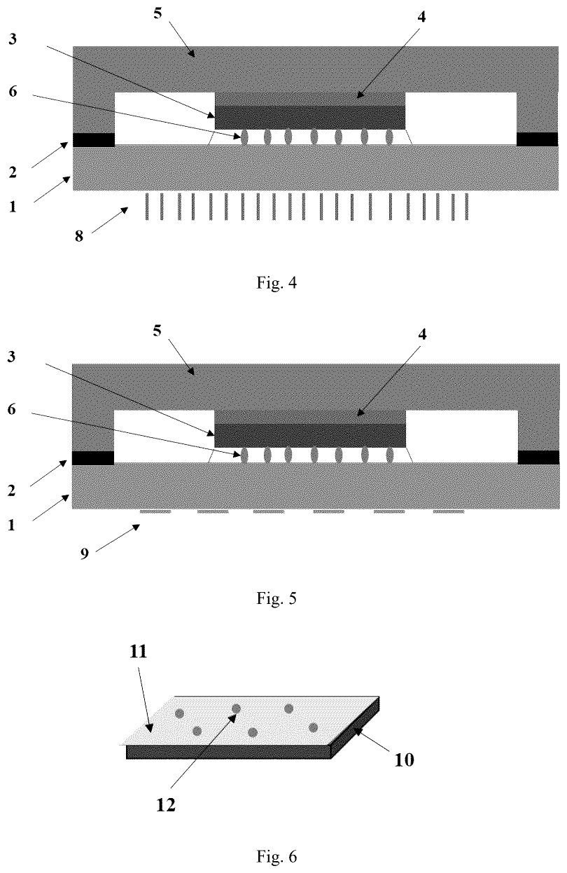

The chip packaging method provided by this embodiment is not limited to specific packaging approaches. For example, the form of BGA packaging, as shown in FIG. 3, includes: a substrate 1, a sealant 2 coated on the substrate 1, a heat dissipation cover plate 5 bonded to the sealant 2, a chip 3 provided on the substrate 1, a layered indium structure 4 provided on the chip 3, and solder balls 7. For example, the form of PGA packaging, as shown in FIG. 4, includes: a substrate 1, a sealant 2 coated on the substrate 1, a heat dissipation cover plate 5 bonded to the sealant 2, a chip 3 provided on the substrate 1, a layered indium structure 4 provided on the chip 3, and solder pins 8. For example, the form of LGA packaging, as shown in FIG. 5, includes: a substrate 1, a sealant 2 coated on the substrate 1, a heat dissipation cover plate 5 bonded to the sealant 2; a chip 3 provided on the substrate 1, a layered indium structure 4 provided on the chip 3, and array-like electrode contacts 9.

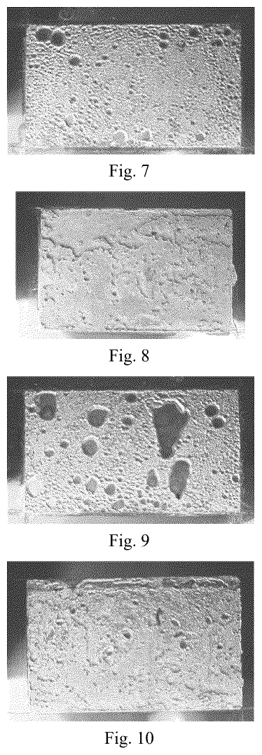

As shown in FIGS. 7-11, a comparison of a coverage rate distribution between the chip 3 packaging method provided by this embodiment and the traditional process using the soldering flux sheet is illustrated. Here, the test conditions are:
the size of an analog chip 3 is 20 mm*35 mm;
the condition for first reflow soldering involves a peak temperature of 170° C. and vacuum; and
the condition for second reflow soldering involves a peak temperature of 260° C. and the absence of vacuum.

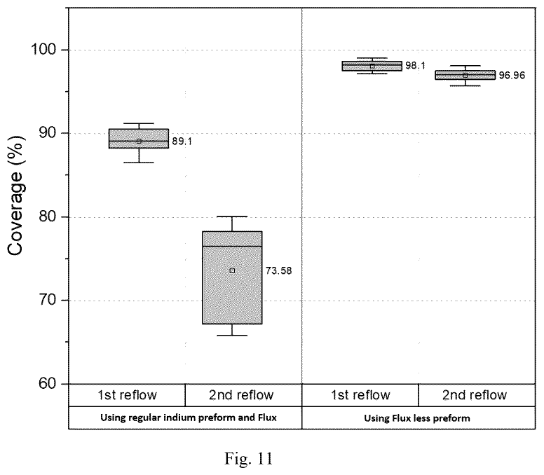

As shown in FIG. 7, after the first reflow soldering, the coverage rate of the traditional process using the soldering flux sheet is 89.1%. As shown in FIG. 8, after the first reflow soldering, the coverage rate of the chip 3 packaging method provided by this embodiment is 98.2%. As shown in FIG. 9, after the second reflow soldering, the coverage rate of the traditional process using the soldering flux sheet is 78.3%. As shown in FIG. 10, after the second reflow soldering, the coverage rate of the chip 3 packaging method provided by this embodiment is 97.5%. FIG. 11 shows a comparison of a coverage rate distribution between the chip 3 packaging method provided by this embodiment and the traditional process using the soldering flux sheet, after the first reflow soldering and the second reflow soldering. It can be seen from FIG. 11 that, under the above test conditions, the chip 3 packaging method provided by the present invention achieves a significant higher coverage rate compared to the traditional process using the soldering flux sheet, and also exhibits a narrower confidence interval.

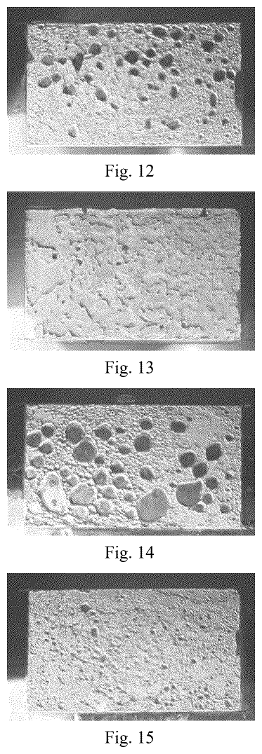

As shown in FIGS. 12-16, a comparison of a coverage rate distribution between the chip 3 packaging method provided by this embodiment and the traditional process using the soldering flux sheet is illustrated. Here, the test conditions are:
the size of an analog chip 3 is 20 mm*35 mm;
the condition for first reflow soldering involves a peak temperature of 170° C. and the absence of vacuum; and
the condition for second reflow soldering involves a peak temperature of 260° C. and the absence of vacuum.

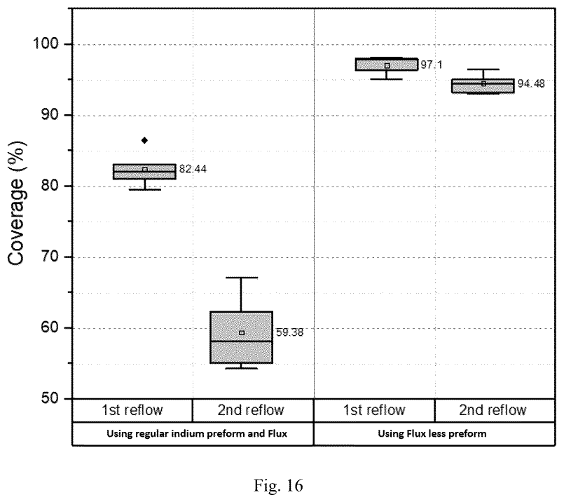

As shown in FIG. 12, after the first reflow soldering, the coverage rate of the traditional process using the soldering flux sheet is 83.1%. As shown in FIG. 13, after the first reflow soldering, the coverage rate of the chip 3 packaging method provided by this embodiment is 97.9%. As shown in FIG. 14, after the second reflow soldering, the coverage rate of the traditional process using the soldering flux sheet is 62.3%. As shown in FIG. 15, after the second reflow soldering, the coverage rate of the chip 3 packaging method provided by this embodiment is 94.5%. FIG. 16 shows a comparison of a coverage rate distribution between the chip 3 packaging method provided by this embodiment and the traditional process using the soldering flux sheet, after the first reflow soldering and the second reflow soldering. It can be seen from FIG. 16 that, under the above test conditions, the chip 3 packaging method provided by the present invention achieves a significant higher coverage rate compared to the traditional process using the soldering flux sheet, and also exhibits a narrower confidence interval. As the vacuum condition changes to the non-vacuum condition, the coverage rate of the traditional process using the soldering flux sheet is significantly reduced due to the removal of the vacuum condition, which greatly affects the soldering effect. However, the chip 3 packaging method provided by this embodiment shows a small decrease in the coverage rate, with no significant impact on soldering.

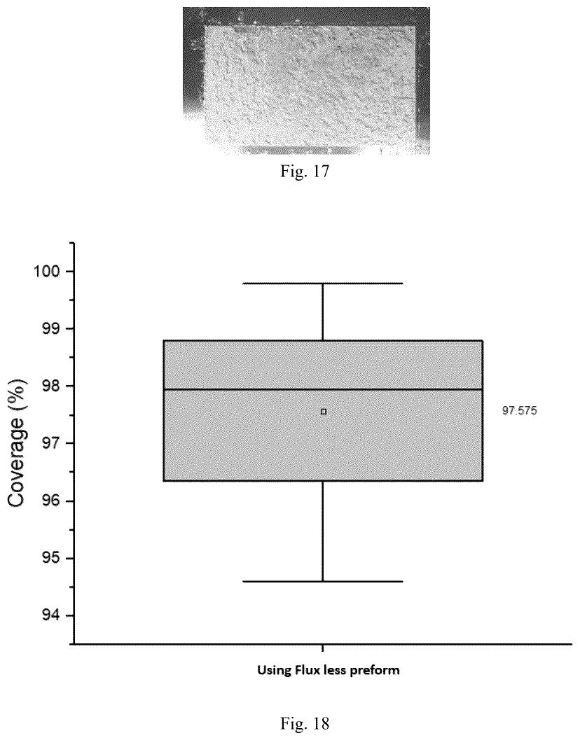

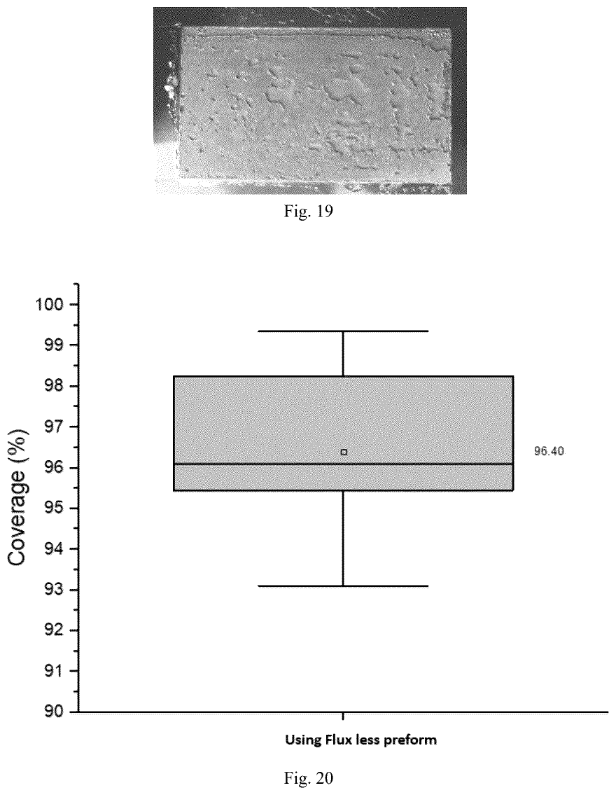

FIG. 17 shows the coverage rate of the process where, in the chip 3 packaging method provided by this embodiment, the reflow soldering process for indium attachment and the reflow soldering process for ball attachment are combined, and a single high-temperature reflow soldering process is employed to replace the two-step low-temperature reflow soldering process for the layered indium structure 4 and the high-temperature reflow soldering process for ball placement. This single high-temperature reflow soldering process cannot be realized by the traditional process using the soldering flux sheet. Here, the test conditions are:
the size of an analog chip 3 is 20 mm*35 mm; and
the condition for reflow soldering involves a peak temperature of 260° C. and the absence of vacuum.

Under the reflow soldering step without indium attachment in advance, as shown in FIG. 17, after the single high-temperature reflow soldering, the coverage rate of the chip 3 packaging method provided by this embodiment is 97.6%. As shown in FIG. 18, a coverage rate distribution of the chip 3 packaging method provided by this embodiment is illustrated, which still exhibits a small confidence interval and a high coverage rate.

FIG. 18 shows a coverage rate where the curing process of the sealant 2 is combined with the indium reflow soldering process.

Here, the test conditions are:
the size of an analog chip 3 is 20 mm*35 mm; and
The curing of the sealant 2 involves performing at 190° C. for 3 minutes and applying a pressure of 100N.

FIG. 19 shows a coverage rate distribution where the curing process of the sealant 2 is combined with the indium reflow soldering process, with a narrower confidence interval than that of the traditional process using the soldering flux sheet, and a higher overall coverage rate than that of the traditional process using the soldering flux sheet.

The chip packaging method provided by this embodiment adopts a process of first curing and sealing and then performing reflow soldering in combination with the protective layer, which avoids a need for a necessary vacuum environment during reflow soldering, reduces the vacuum pumping time, improves the packaging efficiency, and simplifies the process conditions. According to this embodiment, the layered indium structure is obtained by attaching the protective layer to the indium sheet, eliminating the need for the soldering flux. This effectively improves the void conditions of the connecting face, and enhances the coverage rate of the connecting face. Moreover, and the layered indium structure provided with the protective layer achieves a bonding effect comparable to that of the indium sheet with the soldering flux, without impacting the packaging. With improved coverage rate achieved under a condition of the layered indium structure without the soldering flux, this embodiment enables the process to be adjusted and integrate the flows, avoiding the shift between elements, especially the shift of the layered indium structure relative to the chip, and improving the packaging efficiency and stability.

### Embodiment 2

This embodiment provides a chip packaging device, including a first workstation, a second workstation, a third workstation and a fourth workstation.

The first workstation is configured to coat the sealant on the substrate around the chip.

The second workstation is configured to place the layered indium structure on the upper surface of the chip.

The layered indium structure includes at least a surface which is in contact with the chip, and a protective layer on a face opposite to the surface which is in contact with the chip.

The layered indium structure provided by this embodiment has no soldering flux on its surface, and no first soldering flux applying process is needed before the layered indium structure is placed on the upper surface of the chip. After the layered indium structure is placed on the upper surface of the chip, and before the heat dissipation cover plate or another heat dissipation structure is superimposed, no second soldering flux applying process is needed either. This saves the time for applying the soldering flux for two times, and optimizes the process flows. In addition, the layered indium structure without the usage of the soldering flux avoids the risk of the soldering flux residue being trapped between the indium and the chip, or between the indium and the heat dissipation cover plate, thereby preventing void formation in the indium sheet during subsequent reflow soldering.

The area of the layered indium structure 4 is 0.5-30% larger than that of the chip 3, preferably 5-15% larger, more preferably 7-12% larger. The surface of the layered indium structure 4 is coated with a protective layer, which prevents the layered indium structure 4 from being oxidized, and allows the layered indium structure 4 to completely volatilize in the subsequent high temperature process. The temperature of the protective layer is lower than the melting point of indium, so that an oxide-free indium surface can be presented after the protective layer volatilizes. When the reflow soldering process reaches its peak temperature—the melting point of indium, indium melts and serves as the soldering flux to wet the chip 3 and the heat dissipation cover plate 5 and form a bond at the interface, completing soldering. In the traditional indium soldering process, the soldering flux is needed, serving as a temporary glue to attach the indium sheet to the surface of the chip 3. The packaging method provided by this embodiment does not use the soldering flux and achieves temporary adhesion by applying pressure, enabling the layered indium structure 4, serving as thermal interface material (TIM), to be pressed on the chip 3 without the soldering flux, thereby achieving the temporary adhesion. A pressure of more than 0.01 kg (0.1 N/mm²) is needed to be applied per 1 mm² of the layered indium structure 4 without the soldering flux. After the pressure is applied, the layered indium structure 4 will not slide off under a repeated acceleration of more than 5 m/s², that is, higher than the speed of the arms of most fast-moving robots. Therefore, the above process of achieving the adhesion without soldering flux can be handled normally without extra caution. It is unnecessary to apply a force of more than 0.01 kg to every 1 mm² while placing the layered indium structure 4. Regardless of the size of the layered indium structure 4 without the soldering flux, a force of 100N can be applied to a local region of 10*10 mm to achieve a spot adhesion. In addition, the use of droplets can also provide the temporary adhesion. For example, deionized water, isopropanol, ethane alcohol or any liquid with a volatilization temperature below 110° C. can be used.

The surface of the layered indium structure 4 is provided with a protective layer. A method for forming the layered indium structure 4 includes: bringing a solution in which paraffin or resin is dissolved into contact with an indium sheet such that the solution adheres to a surface of the indium sheet, wherein an organic solvent in the solution volatilizes, and the paraffin or resin adheres to the surface of the indium sheet, thereby forming the layered indium structure. A way for bringing the solution in which paraffin or resin is dissolved into contact with the indium sheet includes: placing the indium sheet in the solution, or spraying the solution onto the indium sheet, or the like. This embodiment does not limit the contact approaches, and the implementation of different contact approaches does not affect the realization of the technical effect of this embodiment. The solution is a non-corrosive organic-based solution, which conforms to the regulations for RoHS and REACH, and specifically includes an active agent, paraffin or resin, and organic solvent capable of dissolving the paraffin or resin. The active agent is preferably an organic acid or a combination of the organic acid and an inorganic acid. When the indium sheet is placed in the solution, the surface treatment and the protective layer arrangement both are completed simultaneously. The surface treatment involves removing the oxide layer from the surface of the indium sheet using the organic acid, obtaining a pure indium sheet. Then, the solution is attached to the surface of the pure indium sheet. Upon taking the pure indium sheet out of the solution, the organic solvent capable of dissolving the paraffin or resin volatilizes, leaving the paraffin or resin to be attached to the surface of the pure indium sheet, thereby forming the protective layer for the layered indium structure 4. In this embodiment, an ultra-thin protective layer is provided to protect the surface of the layered indium structure 4, effectively preventing the layered indium structure 4 from being oxidized during subsequent treatment, storage, transportation and the like and before reflow soldering. In the high-temperature environment and during the indium reflow soldering process, the ultra-thin protective layer completely volatilizes, exposing the surface of the oxide-free indium solder to achieve the optimal wetting effect and avoid the void formation.

In some embodiments, an active agent is provided outside the protective layer on the surface of the layered indium structure 4. The active agent is used to clean the oxide from the surface of the protective layer which is in contact with the chip, and the oxide from the surface of the face opposite to the surface of the protective layer which is in contact with the chip. The approach for attaching the active agent to the protective layer on the surface of the layered indium structure 4 is not limited, and can be performed simultaneously during the arrangement of the protective layer, or can be formed by coating and spraying after the protective layer is formed.

The third workstation is configured to place the heat dissipation cover plate on the upper surface of the substrate.

The fourth workstation is configured to cure the sealing material. A method for curing the sealing material includes: curing a first prefabricated member sealing material at a first temperature as a peak temperature, to form a second prefabricated member, where the first temperature is higher than the volatilizing temperature of the protective layer, and the first temperature is low than the melting point of indium. Specifically, the sealant is cured by hot pressing, with a temperature for hot pressing ranges from 30° C. to 150° C., more preferably ranges from 70° C. to 130° C., and more preferably is 120° C. During the curing of the sealant by hot pressing, a sealed cavity is formed between the heat dissipation cover plate and the substrate, providing conditions for subsequent soldering in a non-vacuum environment. At the same time, the protective layer on the surface of the layered indium structure volatilizes with heating, and exposes the surface of the layered indium structure without neither oxidation nor protective layer, which prepares the pure indium to form an intermetallic compound with the metal plating layer on the chip or the heat dissipation cover plate, thereby completing the soldering without the soldering flux.

The fifth workstation is configured to solder the second prefabricated member. A method for soldering the second prefabricated member includes: soldering the second prefabricated member at a second temperature as a peak temperature, where the second temperature is higher than the melting point of indium. Specifically, the chip and the heat dissipation cover plate are connected through the reflow soldering process. The peak temperature of the reflow soldering process ranges from 157° C. to 300° C., preferably is 170° C. Since the surface of the layered indium structure is not oxidized, the heat dissipation cover plate and the substrate have been cured by the sealant, and the periphery of the layered indium structure is in a sealed environment. Therefore, the above reflow soldering process does not need to be performed in a vacuum environment to prevent the layered indium structure from being oxidized. When the temperature during the reflow soldering process reaches the melting point of indium, the layered indium structure wets the chip and forms a bond at the interface. The reflow soldering process provided by this embodiment no longer needs the vacuum environment, which simplifies the packaging processes, and reduces the vacuum pumping time, thereby effectively improving the production efficiency. In some embodiments, the curing process of the sealant can be combined with the indium reflow soldering process, which is especially advantageous for LGA packaging.

The packaging device may further include a sixth workstation, and the sixth workstation is configured to connect a connection structure with a lower surface of the substrate. The connection between the connection structure and the lower surface of the substrate occurs simultaneously with the connection of the second prefabricated member at the second temperature as a peak temperature; or, the connection between the connection structure and the lower surface of the substrate occurs after the connection of the second prefabricated member at the second temperature as a peak temperature, and the connection structure and the lower surface of the substrate are connected at a third temperature as a peak temperature. The type of the connection structure is not limited, and may include solder balls, solder pins, array-like electrode contacts and the like.

The chip packaging method provided by this embodiment is not limited to specific packaging approaches. For example, the form of BGA packaging includes: a substrate, a sealant coated on the substrate, a heat dissipation cover plate combined with the sealant, a chip provided on the substrate, a layered indium structure provided on the chip, and solder balls. For example, the form of PGA packaging includes: a substrate; a sealant coated on the substrate; a heat dissipation cover plate bonded to the sealant; a chip provided on the substrate; a layered indium structure provided on the chip; and solder pins. For example, the form of LGA packaging includes: a substrate, a sealant coated on the substrate, a heat dissipation cover plate bonded to the sealant, a chip provided on the substrate, a layered indium structure provided on the chip, and array-like electrode contacts 9.

Taking BGA packaging as an example, the solder balls are provided on the lower surface of the substrate, and the substrate is connected through the reflow soldering process. The peak temperature for the reflow soldering process ranges from 220° C. to 300° C., preferably is 260° C. Similarly, the above reflow soldering process does not need the vacuum environment.

In some embodiments, the reflow soldering process for the layered indium structure and the reflow soldering process for the solder balls can be combined into a single reflow soldering process, with a peak temperature of 220° C. to 300° C. A single high-temperature reflow soldering process is employed to replace the two-step low-temperature reflow soldering process for the layered indium structure and the high-temperature reflow soldering process for the connection structure. This process simultaneously achieves the soldering of both indium attachment and connection structure attachment.

In some embodiments, the second workstation and the third workstation are the same workstation, which sequentially performs the placement of the layered indium structure on the upper surface of the chip and the placement of the heat dissipation structure on the upper surface of the substrate. The layered indium structure is placed on the upper surface of the chip at this workstation. Without the need for workstation turnover, at the same workstation, the heat dissipation cover plate is placed on the upper surface of the substrate where the layered indium structure has been placed. Since the heat dissipation cover plate is pressed on the layered indium structure, even if the packaging structure moves in the subsequent process, the layered indium structure will not shift from the fixed position on the upper surface of the chip, which improves the packaging stability. In some embodiments, the first workstation, the second workstation and the third workstation are the same workstation, which sequentially performs the arrangement of the sealing material on the substrate on which the chip is placed, the placement of the layered indium structure on the upper surface of the chip and the placement of the heat dissipation structure on the upper surface of the substrate. The above approach, by completing various layout tasks at the same workstation, avoids the circulation of semi-finished products between workstations, reduces the possibility of relative positional shift between components, and improves the packaging stability.

In some embodiments, the fourth workstation and the fifth workstation are the same workstation, which sequentially performs the curing of the sealing material and the connection of the second prefabricated member. In some embodiments, the fifth workstation and the sixth workstation are the same workstation, which sequentially performs the connection of the second prefabricated member and the connection of the connection structure with the lower surface of the substrate, or simultaneously performs the connection of the second prefabricated member and the connection of the connection structure with the lower surface of the substrate. In some embodiments, the fourth workstation, the fifth workstation and the sixth workstation are the same workstation, which sequentially performs the curing of the sealing material, the connection of the second prefabricated member and the connection of the connection structure with the lower surface of the substrate; or, after performing the curing of the sealing material, simultaneously performs the connection of the second prefabricated member and the connection of the connection structure with the lower surface of the substrate. The above approach, by completing various layout tasks at the same workstation, improves the utilization of devices, reduces the overall volume of the packaging device, reduces the circulation of semi-finished products, and enables the same workstation to accommodate diverse heating temperatures simultaneously, thereby significantly improving the preparation efficiency.

The chip packaging device provided by this embodiment adopts a process of first curing and sealing and then performing reflow soldering in combination with the protective layer, which avoids a need for a necessary vacuum environment during reflow soldering, reduces the vacuum pumping time, improves the packaging efficiency, and simplifies the process conditions. According to this embodiment, the layered indium structure is obtained by attaching the protective layer to the indium sheet, eliminating the need for the soldering flux. This effectively improves the void conditions of the connecting face, and enhances the coverage rate of the connecting face. Moreover, the layered indium structure provided with the protective layer achieves a bonding effect comparable to that of the indium sheet with the soldering flux, without impacting the packaging. With improved coverage rate achieved under a condition of the layered indium structure without the soldering flux, this embodiment enables the process to be adjusted and integrates the flows, avoiding the shift between elements, especially the shift of the layered indium structure relative to the chip, and improving the packaging efficiency and stability.

For purposes of illustration, the foregoing description uses specific names to provide a thorough understanding of the embodiments. However, it will be apparent to those skilled in the art that the embodiments may be practiced without specific details. Therefore, for purposes of illustration and description, the foregoing description of specific embodiments described herein have been presented. Such description is not intended to be exhaustive or to limit the embodiments to the precise forms disclosed. It will be apparent to ordinary skilled in the art that many modifications and variations are possible in view of the above teachings. Additionally, when used herein to refer to positions of components, the terms in the above and in the following or their synonyms do not necessarily refer to absolute positions relative to an external reference, but refer to relative positions of components with reference to the drawings.

In addition, the foregoing drawings and description include numerous concepts and features, which can be combined in various ways to achieve diverse beneficial effects and advantages. Therefore, the features, components, elements and/or concepts from various drawings can be combined to produce embodiments or implementations that may not necessarily be shown or described in this specification. In addition, in any embodiment and/or implementation, not all the features, components, elements and/or concepts shown in the specific drawings or illustrations are necessarily required. It should be understood that such embodiments and/or implementations fall within the scope of this specification.

What is claimed:

1. A chip packaging method, comprising:
arranging a sealing material on a substrate on which a chip is placed;
placing, on an upper surface of the chip, a layered indium structure which includes at least a protective layer for a surface which is in contact with the chip, and a protective layer for a face opposite to the surface which is in contact with the chip;
placing, on an upper surface of the substrate, a heat dissipation structure which is bonded to the sealing material to form a first prefabricated member;
curing the sealing material in the first prefabricated member at a first temperature as a peak temperature, to form a second prefabricated member; and
connecting the chip, the layered indium structure and the heat dissipation structure of the second prefabricated member at a second temperature as a peak temperature;
wherein the first temperature is lower than a melting point of indium, and the second temperature is higher than the melting point of indium; and
the protective layer volatilizes before the layered indium structure melts.

2. The chip packaging method according to claim 1, wherein connecting the second prefabricated member at the second temperature as the peak temperature is not limited to a vacuum environment.

3. The chip packaging method according to claim 1, wherein a method for forming the layered indium structure comprises: bringing a solution in which paraffin or resin is dissolved into contact with an indium sheet such that the solution adheres to a surface of the indium sheet, wherein an organic solvent in the solution volatilizes, and the paraffin or resin adheres to the surface of the indium sheet, thereby forming the layered indium structure.

4. The chip packaging method according to claim 1, further comprising: arranging a connection structure on a lower surface of the substrate; wherein:
the connection between the connection structure and the lower surface of the substrate occurs simultaneously with the connection of the second prefabricated member at the second temperature as the peak temperature;
or,
the connection between the connection structure and the lower surface of the substrate occurs after the connection of the second prefabricated member at the second temperature as the peak temperature, and the connection structure and the lower surface of the substrate are connected at a third temperature as a peak temperature.

5. The chip packaging method according to claim 4, wherein the connection structure is solder balls.

6. The chip packaging method according to claim 1, wherein the first temperature ranges from 30° C. to 150° C.

7. The chip packaging method according to claim 1, wherein the second temperature ranges from 157° C. to 300° C.

8. The chip packaging method according to claim 4, wherein,
when the connection between the connection structure and the lower surface of the substrate occurs simultaneously with the connection of the second prefabricated member at the second temperature as the peak temperature, the second temperature ranges from 220° C. to 300° C.; and
when the connection between the connection structure and the lower surface of the substrate occurs after the connection of the second prefabricated member at the second temperature as the peak temperature, and the connection structure and the lower surface of the substrate are connected at the third temperature as the peak temperature, the second temperature ranges from 157° C. to 200° C., and the third temperature ranges from 220° C. to 300° C.

9. The chip packaging method according to claim 1, wherein an active agent is provided outside the protective layer, and the active agent is used to clean the surface of the protective layer which is in contact with the chip, and the surface of the face opposite to the surface of the protective layer which is in contact with the chip.

10. A chip packaging device, comprising: a first workstation, a second workstation, a third workstation, a fourth workstation and a fifth workstation; wherein
the first workstation is configured to arrange a sealing material on a substrate on which a chip is placed;
the second workstation is configured to place, on an upper surface of the chip, a layered indium structure which includes at least a protective layer for a surface which is in contact with the chip, and a protective layer for a face opposite to the surface which is in contact with the chip;
the third workstation is configured to place, on an upper surface of the substrate, a heat dissipation structure to form a first prefabricated member;
the fourth workstation is configured to cure the sealing material to form a second prefabricated member; and a method for curing the sealing material comprises: curing the sealing material at a first temperature as a peak temperature;
wherein the first temperature is lower than a melting point of indium;
the fifth workstation is configured to connect the second prefabricated member, and a method for connecting the second prefabricated member comprises: connecting the chip, the layered indium structure and the heat dissipation structure of the second prefabricated member at a second temperature as a peak temperature;
wherein the second temperature is higher than the melting point of indium; and the protective layer volatilizes before the layered indium structure melts.

11. The chip packaging device according to claim 10, wherein the connecting the second prefabricated member at the second temperature as the peak temperature is not limited to a vacuum environment.

12. The chip packaging device according to claim 10, further comprising a sixth workstation, wherein the sixth workstation is configured to connect a connection structure with a lower surface of the substrate;
the connection between the connection structure and the lower surface of the substrate occurs simultaneously with the connection of the second prefabricated member at the second temperature as the peak temperature;
or,
the connection between the connection structure and the lower surface of the substrate occurs after the connection of the second prefabricated member at the second temperature as the peak temperature, and the connection structure and the lower surface of the substrate are connected with a third temperature as a peak temperature.

13. The chip packaging device according to claim 12, wherein the connection structure is solder balls.

14. The chip packaging device according to claim 10, wherein the first temperature ranges from 30° C. to 150° C.

15. The chip packaging device according to claim 10, wherein the second temperature ranges from 157° C. to 300° C.

16. The chip packaging device according to claim 12, wherein:
when the connection between the connection structure and the lower surface of the substrate occurs simultaneously with the connection of the second prefabricated member at the second temperature as the peak temperature, the second temperature ranges from 220° C. to 300° C.; and
when the connection between the connection structure and the lower surface of the substrate occurs after the connection of the second prefabricated member at the second temperature as the peak temperature, and the connection structure and the lower surface of the substrate are connected at the third temperature as the peak temperature, the second temperature ranges from 157° C. to 200° C., and the third temperature ranges from 220° C. to 300° C.

17. The chip packaging device according to claim 10, wherein the second workstation and the third workstation are the same workstation, which sequentially performs the placement of the layered indium structure on the upper surface of the chip and the placement of the heat dissipation structure on the upper surface of the substrate.

18. The chip packaging device according to claim 10, wherein the first workstation, the second workstation and the third workstation are the same workstation, which sequentially performs the arrangement of the sealing material on the substrate on which the chip is placed, the placement of the layered indium structure on the upper surface of the chip and the placement of the heat dissipation structure on the upper surface of the substrate.

19. The chip packaging device according to claim 10, wherein the fourth workstation and the fifth workstation are the same workstation, which sequentially performs the curing of the sealing material and the connection of the second prefabricated member.

20. The chip packaging device according to claim 12, wherein the fifth workstation and the sixth workstation are the same workstation, which sequentially performs the connection of the second prefabricated member and the connection of the connection structure with the lower surface of the substrate, or simultaneously performs the connection of the second prefabricated member and the connection of the connection structure with the lower surface of the substrate.

21. The chip packaging device according to claim 12, wherein the fourth workstation, the fifth workstation and the sixth workstation are the same workstation, which sequentially performs the curing of the sealing material, the connection of the second prefabricated member, and the connection of the connection structure with the lower surface of the substrate;
or, after performing the curing of the sealing material, simultaneously performs the connection of the second prefabricated member and the connection of the connection structure with the lower surface of the substrate.
